(19) United States
(12) Patent Application Publication
(10) Pub. No.: US 2006/0097283 A1
(43) Pub. Date: May 11, 2006

(54) Group III-nitride-based compound semiconductor device

(76) Inventor: Tetsuya Taki, Aichi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 10/542,780

(22) PCT Filed: Sep. 1, 2004
(86) PCT No.: PCT/JP04/13082

§ 371 Date: Sep. 27, 2005

(30) Foreign Application Priority Data
Sep. 16, 2003 (JP) 2003-322541

(51) Int. Cl. H01L 31/109

(52) U.S. Cl. 257/200

(57) ABSTRACT

In a group III-nitride-based compound semiconductor device 100, an intermediate layer 108 is 5 provided between a p-AlGaN layer 107 and a p-GaN layer 109, to each of which an acceptor impurity is added. On this occasion, the intermediate layer 108 is doped with a donor impurity in a concentration, by which holes generated by an acceptor impurity introduced into the intermediate layer 108 during the formation of the p-AlGaN layer 107 are substantially compensated. As a result, the conductivity of the intermediate layer 108 becomes extremely low, and therefore the electrostatic withstand voltage of the group III-nitride-based compound semiconductor device 100 improves significantly.

The present application is based on Japanese patent application No. 2003-322541, the entire contents of which are incorporated herein by reference.

### BACKGROUND OF THE INVENTION

1. Field of the Invention

The present invention relates to a group III-nitride-based compound semiconductor device and, more particularly to a group III-nitride-based compound semiconductor device that has a high electrostatic withstand voltage.

2. The Related Art of the Invention

A group III-nitride-based compound semiconductor device is coming into general use as a light emitting device, for example, in the green, the blue, and the ultraviolet region. However, the properties of the group III-nitride-based compound semiconductor device still leave room for improvement, except for luminescence intensity. Especially, the electrostatic withstand voltage thereof is by far lower than that of a gallium-arsenic-based or an indium-phosphorous-based light emitting device, and thus an extensive improvement in the electrostatic withstand voltage is needed.

Japanese patent application laid-open No. 2001-148507 discloses a technique that improves the electrostatic withstand voltage of a group III-nitride-based compound semiconductor light emitting device. The technique thereof is to provide a p-type low-concentration doped layer, in which a low concentration of acceptor impurity is doped, or an undoped layer in which a minor amount of acceptor impurity is inadvertently doped, between a p-cladding layer and a p-contact layer. According to this particular technique, it is necessary that the p-type low-concentration doped layer has a thickness of approximately 200 nm. However, this layer has a high resistivity and yet a large thickness, which causes an increase in the resistance thereof. Consequently, this layer is considered to increase a voltage for driving the device.

### SUMMARY OF THE INVENTION

The present invention has been completed based on the concept that the driving voltage is further lowered by decreasing the acceptor impurity of p-type low-concentration doped layer and by decreasing the thickness of p-type low-concentration doped layer.

It is an object of the present invention to provide a group III-nitride-based compound semiconductor device that has an improved electrostatic withstand voltage as well as reduced driving voltage.

According to the first aspect of the present invention, a group III-nitride-based compound semiconductor device comprises:

a first p-layer and a second p-layer, to each of which an acceptor impurity is added; and

an intermediate layer provided between the first p-layer and the second p-layer,

wherein the intermediate layer is doped with a donor impurity of such a concentration that a hole generated by an acceptor impurity inadvertently introduced into the intermediate layer during its manufacturing process is substantially compensated.

The wording “substantially compensates for the generation of holes” means that holes which could be generated by the concentration of the acceptor impurity are cancelled out by electrons generated by the donor impurity and as a result a hole concentration in the intermediate layer is substantially the same as that in a group III-nitride-based compound semiconductor with no impurity added. The hole concentration may preferably be decreased to equal to or less than 10¹⁷/cm³, for example.

The donor impurity doped into the intermediate layer may be doped with a concentration distribution corresponding to a concentration distribution of the acceptor impurity in the intermediate layer.

The expression “a concentration distribution corresponding to a concentration distribution of the acceptor impurity in the intermediate layer” is the one that takes into account an activation rate. More specifically, if the activation rate of the acceptor impurity is equal to that of the donor impurity, the concentration distribution of the donor impurity in the direction of thickness is made to substantially correspond to that of the acceptor impurity in the direction of thickness. If the activation rate of the acceptor impurity is one-tenth of that of the donor impurity, the concentration distribution of the donor impurity in the direction of thickness is made substantially equal to one-tenth of that of the acceptor impurity in the direction of thickness.

The acceptor impurity may be magnesium (Mg) and the donor impurity may be silicon (Si).

Silicon may have a concentration distribution substantially 1/10 that of magnesium.

The intermediate layer may have a hole concentration equal to or less than 10¹⁷/cm³.

The first p-layer may include a p-cladding layer made of p-type AlGaN doped with Mg, and the second p-layer may include a p-contact layer made of p-type GaN doped with Mg.

According to the second aspect of the present invention, a group III-nitride-based compound semiconductor device comprises:

a sapphire substrate;

an n-contact layer formed on the sapphire substrate;

an n-cladding layer formed on the n-contact layer;

a light emitting layer formed on the n-cladding layer;

a p-cladding layer and a p-contact layer, to each of which an acceptor impurity is added; and

an intermediate layer provided between the p-cladding layer and the p-contact layer,

a thin film p-electrode disposed on the p-contact layer;

a thick film p-electrode disposed on the thin film p-electrode; and

an n-electrode disposed on the n-contact layer, wherein the intermediate layer is doped with a donor impurity in a concentration, by which holes generated by an acceptor impurity introduced therein during a manufacturing process are substantially compensated.

The light emitting layer may include a multiquantum well structure formed on the n-cladding layer by laminating multiple pairs of well layers of undoped InGaN and barrier layers of undoped GaN.

The thin film p-electrode may be formed of a first layer of cobalt and a second layer of gold. The thick film p-electrode may be formed by laminating a first layer of vanadium, a second layer of gold, and a third layer of aluminum in sequence, on the thin film p-electrode. The n-electrode may be formed by laminating a first layer of vanadium and a second layer of aluminum on a partly exposed portion of the n-contact layer.

A reflective metal layer of aluminum may be formed on the lower surface of the sapphire substrate.

The intermediate layer according to the present invention exhibits an extremely low conductivity. Even if the intermediate layer is as thin as 100 nm or less, the electrostatic withstand voltage of the group III-nitride-based compound semiconductor device will significantly improve. In addition, there is almost no increase in the driving voltage due to the provision of the intermediate layer, and the properties of the group III-nitride-based compound semiconductor do not deteriorate. With respect to an action that provides such effects, the intermediate layer of the present invention is considered to be effective in exerting an action by which an applied voltage does not concentrate on a part of the p-electrode side but extends widely across the p-electrode side.

### BRIEF DESCRIPTION OF THE DRAWINGS

FIG. 1 is a cross-sectional view of a group III-nitride-based compound semiconductor device 100 according to an embodiment of the present invention, and

FIG. 2 is a schematic diagram of concentration distributions of magnesium and silicon in an intermediate layer of the group III-nitride-based compound semiconductor device 100 according to the embodiment of the present invention.

### DETAILED DESCRIPTION OF THE PREFERRED EMBODIMENT

A preferred embodiment of the present invention will now be described. The “an acceptor impurity inadvertently introduced in a layer during its manufacturing process” means an acceptor impurity mixed thereinto for somewhat technical reason although the acceptor impurity is not intentionally mixed when forming the concerned layer.

The technical reasons include migration from an adjacent layer, contamination due to an imperfect changeover of introduced raw materials at a time of transition when a different layer is formed (so-called memory effect), and contamination “constantly” generated in a trace amount due to, for example, inadequate cleaning of manufacturing equipment. In the embodiment described below, it is assumed that the acceptor impurity is not deliberately incorporated into the intermediate layer, but is spontaneously mixed into it in the following manufacturing process.

The donor impurity is added in accordance with a measurement of a concentration distribution of the acceptor impurity to be mixed through the formation of the intermediate layer as described above. If the acceptor impurity is magnesium and the donor impurity is silicon, it is necessary to determine a concentration distribution of the silicon taking into account the activation rates of magnesium and silicon. Since the activation rate of magnesium is approximately one-tenth of that of silicon, silicon should be added with a concentration distribution corresponding to one-tenth of the concentration distribution of magnesium.

The constructions of the first p-layer and the second p-layer are arbitrary. When a light emitting device is formed, an n-side layer(s) (one or more layers, possibly including multiple layers), a light emitting layer, a first p-layer, an intermediate layer, and a second p-layer are laminated in sequence, and on the second p-layer, an electrode is formed. In this case, it is recommended that a group III-nitride-based compound semiconductor layer, to which the acceptor impurity is added, be adjusted so that a band gap becomes smaller in the order of the first p-layer, the intermediate layer, and the second p-layer. In addition, the construction is not limited to the above simple construction, and deliberate addition of multiple layers with various actions or a layer with any impurity added is also covered by the present invention.

When a light emitting device is formed, it is preferred that a multiquantum well structure which makes up a light emitting layer include a well layer which consists of a group III-nitride-based compound semiconductor Al_{y}Ga_{1-y-z}In_{z}N (0≦y<1, 0<z≦1) containing at least indium (In). Constituent elements of the light emitting layer include, for example, a well layer of doped or undoped Ga_{1-z}In_{z}N (0<z≦1) and a barrier layer of a group III-nitride-based compound semiconductor AlGaInN of any composition having a larger band gap than the well layer. A preferable example is a combination of a well layer of undoped Ga_{1-z}In_{z}N (O<z<l) and a barrier layer of undoped GaN.

The group III-nitride-based compound semiconductor device according to the present invention can be arbitrarily constructed. In particular, the light emitting device can be a light emitting diode (LED), a laser diode (LD), a photo coupler, or any other light emitting devices. For the manufacture of the group III-nitride-based compound semiconductor light emitting device, any manufacturing method can be used.

Specifically, sapphire, spinel, Si, SiC, ZnO, MgO, or a group III-nitride-based compound single crystal can be used as a substrate that allows crystal growth. As a method that allows the crystal growth of a group III-nitride-based compound semiconductor layer, molecular beam epitaxy (MBE), metalorganic vapor phase epitaxy (MOVPE), hydride vapor phase epitaxy (HVPE), liquid phase epitaxy or the like is effective.

The group III-nitride semiconductor layer such as an electrode formation layer can be formed by a group III-nitride-based compound semiconductor which comprises a binary, ternary or quaternary semiconductor represented at least by AlₓGa_{y}In₁₋ₓ₋ₓN (0≦x≦1, 0≦y≦1, 0≦x+y≦1). Further, a part of these group III elements may be replaced by boron (B) or thallium (Tl), and a part of nitrogen (N) may be replaced by phosphorus (P), arsenic (As), antimony (Sb), or bismuth (Bi).

In addition, when these semiconductors are used to form an n-type group III-nitride-based compound semiconductor layer, Si, Ge, Se, Te, C, or the like can be added as an n-type impurity, and Zn, Mg, Be, Ca, Sr, Ba, or the like can be added as a p-type impurity.

By means of the foregoing aspects of the present invention, the above-mentioned problem can be solved effectively or rationally.

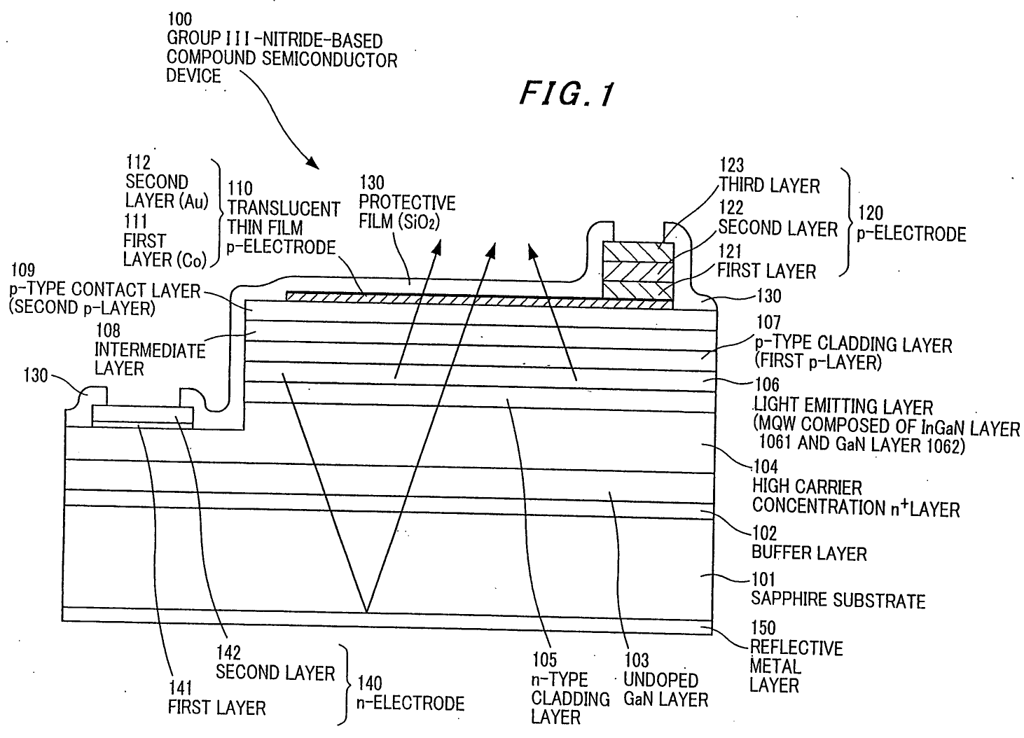

FIG. 1 shows a schematic cross-sectional view of a group III-nitride-based compound semiconductor device 100 according to an embodiment of the present invention. The group III-nitride-based compound semiconductor device 100 is a light emitting device having the following construction: As illustrated in FIG. 1, on a sapphire substrate 101 approximately 300 μm thick, a buffer layer 102 of aluminum nitride (AlN) having a film thickness of approximately 15 nm is formed, a layer 103 of undoped GaN having a film thickness of approximately 500 nm is formed thereon, and an n-type contact layer 104 (high carrier concentration n⁺ layer) of Ga doped with 1×10¹⁸/cm³ of silicon (Si) having a film thickness of approximately 5 μm is formed thereon.

Also, on this n-type contact layer 104, an n-type cladding layer 105 of Al_{0.15}Ga_{0.85}N doped with 1×10¹⁸/cm³ of silicon (Si) having a film thickness of 25 nm is formed. Further, a light emitting layer 106 of multiquantum well structure is formed thereon by laminating three pairs of well layers 1061 of undoped In_{0.2}Ga_{0.8}N, each having a film thickness of 3 nm and barrier layers 1062 of undoped GaN, each having a film thickness of 20 nm.

Furthermore, on this light emitting layer 106, a p-type cladding layer (a first p-layer) 107 of p-type Al_{0.15}Ga_{0.85}N doped with 2×10¹⁹/cm³ of Mg having a film thickness of 25 nm is formed. On the p-type layer 107, an intermediate layer 108 doped with silicon (Si) with a concentration distribution of 2×10¹⁸ to 3×10¹⁷/cm³ and having a film thickness of 100 nm is formed. On the intermediate layer 108, a p-type contact layer (a second p-layer) 109 of p-type GaN doped with 8×10¹⁹/cm³ of Mg having a film thickness of 100 nm is formed.

Further, a translucent thin film p-electrode 110 is formed by metal evaporation on the p-type contact layer (the second p-layer) 109 and an n-electrode 140 is formed on the n-type contact layer 104. The translucent thin film p-electrode 110 is composed of a first layer 111 of cobalt (Co) having a film thickness of approximately 1.5 nm which is joined directly to the p-type contact layer (the second p-layer) 109 and a second layer 112 of gold (Au) having a film thickness of approximately 6 nm which is joined to this cobalt film.

A thick film p-electrode 120 is constructed by laminating a first layer 121 of vanadium (V) having a film thickness of approximately 18 nm, a second layer 122 of gold (Au) having a film thickness of approximately 15 μm, and a third layer 123 of aluminum (Al) having a film thickness of approximately 10 nm in sequence, on the translucent thin film p-electrode 110.

The n-electrode 140 of multilayer structure is constructed by laminating a first layer 141 of vanadium (V) having a film thickness of approximately 18 nm and a second layer 142 of aluminum (Al) having a film thickness of approximately 100 nm on a partly exposed portion of the n-type contact layer 104.

Further, on the uppermost face, a protective film 130 comprising a SiO₂ film is formed. On the outer undermost face corresponding to the undersurface of the sapphire substrate 101, a reflective metal layer 150 of aluminum (Al) having a film thickness of approximately 500 nm is formed by metal evaporation. In addition, this reflective metal layer 150 may be of nitride such as TiN or HfN as well as metal such as Rh, Ti, or W.

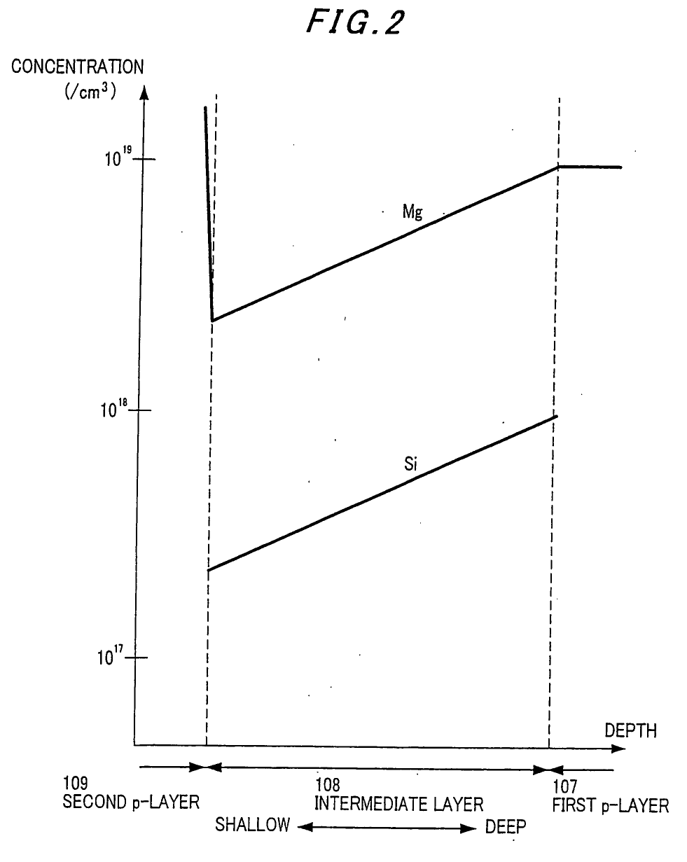

The basis of the concentration distribution of silicon in the intermediate layer 108 is as follows: A concentration distribution of magnesium when silicon is not added to the intermediate layer was measured as indicated by Mg shown in FIG. 2. Then, in view of the fact that the activation rate of magnesium (hole concentration/magnesium concentration when excited at room temperature) is approximately one-tenth of that of silicon (electron concentration/silicon concentration when excited at room temperature), silicon is added to the intermediate layer in such a manner that the concentration distribution of silicon in the direction of thickness corresponds to one-tenth of that of magnesium in the direction of thickness (Si shown in FIG. 2). This allows the concentration of holes excited by magnesium to be compensated by the concentration of electrons excited by silicon. Consequently, the carrier concentration in the intermediate layer can be considerably decreased, for example, to 10¹⁶ to 10¹⁷/cm³ or less.

The group III-nitride-based compound semiconductor device 100 thus constructed as shown in FIG. 1 shows an improved electrostatic withstand voltage, compared with the one in which the intermediate layer 108 is not formed. Also, the group III-nitride-based compound semiconductor device can have a thinner intermediate layer, compared with the one in which the intermediate layer 108 is not doped with silicon, and therefore it is possible to reduce the driving voltage as well as to improve the electrostatic withstand voltage.

In accordance with the present invention, the holes caused by the acceptor impurity are compensated by electrons as described above. Therefore, it is preferred that the hole concentration should be reduced by adding a donor. In other words, the concentration distribution of the hole depending on that of the acceptor impurity does not have to be completely compensated by the concentration distribution of the donor impurity.

The present invention is not limited to the above embodiment and other different variations are possible. For example, each group III-nitride-based compound semiconductor layer can be binary to quaternary AlGaIn of any mixed crystal ratio. More specifically, a binary, ternary (GaInN, AlInN, AlGaN) or quaternary (AlGaInN) group III-nitride-based compound semiconductor, which is represented by a general formula: AlₓGa_{y}In_{1-x-y}N (0≦x≦1, 0≦y≦1, 0≦x+y≦1), can be used. A part of the N of such a compound may be replaced by a group V element such as P or As. Additionally, the protective film 130 is formed in the above-mentioned embodiment, but it may be omitted. Also, in the same embodiment, the reflective metal layer is formed on the undersurface of the sapphire substrate and the translucent thin film p-electrode is provided at the p-electrode side, but in order to produce a flip chip type, instead of forming the reflective metal layer on the undersurface of the sapphire substrate, an electrode layer which also serves as a light reflection layer may be provided at the p-electrode side so as to build a structure that permits taking out light from the undersurface of the sapphire substrate.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing description of the embodiments according to the present invention is provided for illustration only, and not for the purpose of limiting the invention as defined by the appended claims and their equivalents.

1. A group III-nitride-based compound semiconductor device, comprising:
a first p-layer and a second p-layer, to each of which an acceptor impurity is added; and
an intermediate layer provided between the first p-layer and the second p-layer,
wherein the intermediate layer is doped with a donor impurity of such a concentration that a hole generated by an acceptor impurity inadvertently introduced into the intermediate layer during its manufacturing process is substantially compensated.

2. The group III-nitride-based compound semiconductor device according to claim 1, wherein:
the donor impurity doped into the intermediate layer is doped with a concentration distribution corresponding to a concentration distribution of the acceptor impurity in the intermediate layer.

3. The group III-nitride-based compound semiconductor device according to claim 1, wherein:
the acceptor impurity is magnesium and the donor impurity is silicon.

4. The group III-nitride-based compound semiconductor device according to claim 3, wherein:
the donor impurity of silicon has a concentration distribution substantially 1/10 that of the acceptor impurity of magnesium.

5. The group III-nitride-based compound semiconductor device according to claim 1, wherein:
the intermediate layer has a hole concentration equal to or less than 10¹⁷/cm³.

6. The group III-nitride-based compound semiconductor device according to claim 1, wherein:
the first p-layer includes a p-cladding layer made of p-type AlGaN doped with Mg, and the second p-layer includes a p-contact layer made of p-type GaN doped with Mg.

7. A group III-nitride-based compound semiconductor device, comprising:
a sapphire substrate;
an n-contact layer formed on the sapphire substrate;
an n-cladding layer formed on the n-contact layer;
a light emitting layer formed on the n-cladding layer;
a p-cladding layer and a p-contact layer, to each of which an acceptor impurity is added;
an intermediate layer provided between the p-cladding layer and the p-contact layer,
a thin film p-electrode disposed on the p-contact layer;
a thick film p-electrode disposed on the thin film p-electrode; and
an n-electrode disposed on the n-contact layer,
wherein the intermediate layer is doped with a donor impurity in a concentration, by which holes generated by an acceptor impurity introduced therein during a manufacturing process are substantially compensated.

8. The group III-nitride-based compound semiconductor device according to claim 7, wherein:
the light emitting layer includes a multiquantum well structure formed on the n-cladding layer by laminating multiple pairs of well layers of undoped InGaN and barrier layers of undoped GaN.

9. The group III-nitride-based compound semiconductor device according to claim 7, wherein:
the thin film p-electrode is formed of a first layer of cobalt and a second layer of gold;
the thick film p-electrode is formed by laminating a first layer of vanadium, a second layer of gold, and a third layer of aluminum in sequence, on the thin film p-electrode; and
the n-electrode is formed by laminating a first layer of vanadium and a second layer of aluminum on a partly exposed portion of the n-contact layer.

10. The group III-nitride-based compound semiconductor device according to claim 7, further comprising:
a reflective metal layer of aluminum formed on the lower surface of the sapphire substrate.
